(19) United States
(12) Patent Application Publication
(10) Pub. No.: US 2026/0186089 A1
(43) Pub. Date: Jul. 2, 2026

(54) GRADIENT COILS AND MAGNETIC RESONANCE IMAGING DEVICES

(71) Applicant: SHANGHAI UNITED IMAGING HEALTHCARE CO., LTD., Shanghai (CN)

(72) Inventors: Jiwen YANG, Shanghai (CN); Shuguang LIU, Shanghai (CN); Kejia NIU, Shanghai (CN); Yuan GAO, Shanghai (CN); Man FAN, Shanghai (CN); Lifeng WANG, Shanghai (CN); Tao WANG, Shanghai (CN); Peng WANG, Shanghai (CN)

(73) Assignee: SHANGHAI UNITED IMAGING HEALTHCARE CO., LTD., Shanghai (CN)

(21) Appl. No.: 19/435,967

(22) Filed: Dec. 30, 2025

(30) Foreign Application Priority Data
Dec. 30, 2024 (CN) 202411984462.1

(51) Int. Cl. G01R 33/385

(52) U.S. Cl. CPC G01R 33/3856

(57) ABSTRACT

The present disclosure related to a gradient coil. The gradient coil includes a plurality of conductor structures, each of the plurality of conductor structures includes one or more coil units wound in a concentric manner, each of the one or more coil units includes a plurality of hollow conductors, and a conduit for a cooling medium to pass through is disposed within each of the plurality of hollow conductors, the plurality of hollow conductors are connected in series in a circuit, and at least two conduits of the plurality of hollow conductors are connected in parallel.

### CROSS-REFERENCE TO RELATED APPLICATIONS

This application claims priority to the Chinese Patent Application No. 202411984462.1, filed on Dec. 30, 2024, the contents of which are hereby incorporated by reference.

### TECHNICAL FIELD

The present disclosure relates to the field of magnetic resonance (MR) technology, and in particular to a gradient coil and a magnetic resonance imaging device.

### BACKGROUND

Magnetic resonance imaging (MRI) is a technique that uses a static magnetic field, a gradient magnetic field, and radio frequency pulses to non-invasively acquire internal structural and physiological information of a human body. A gradient coil of a magnetic resonance imaging device is capable of generating the gradient magnetic field to achieve spatial encoding.

Therefore, it is desirable to provide a gradient coil with an optimized design to meet usage requirements with higher standards.

### SUMMARY

One or more embodiments of the present disclosure provide a gradient coil. The gradient coil includes a plurality of conductor structures, each of the plurality of conductor structures includes one or more coil units wound in a concentric manner, each of the one or more coil units includes a plurality of hollow conductors, and a conduit for a cooling medium to pass through is disposed within each of the plurality of hollow conductors, the plurality of hollow conductors are connected in series in a circuit, and at least two conduits of the plurality of hollow conductors are connected in parallel.

In some embodiments, the gradient coil includes one or more electro-hydraulic separation adapter devices, wherein each of the one or more electro-hydraulic separation adapter devices effects a series circuit connection between a pair of the plurality of hollow conductors.

In some embodiments, the electro-hydraulic separation adapter device includes a first connecting conductor, the coil unit includes a first hollow conductor and a second hollow conductor, one end of the first hollow conductor and one end of the second hollow conductor are electrically connected by the first connecting conductor.

In some embodiments, the electro-hydraulic separation adapter device leads out the cooling medium from a conduit of one of the pair of the plurality of hollow conductors.

In some embodiments, the electro-hydraulic separation adapter device introduces the cooling medium into the other of the pair of the plurality of hollow conductors.

In some embodiments, the electro-hydraulic separation adapter device includes a first medium interface, the coil unit includes a first hollow conductor and a second hollow conductor, one end of the first hollow conductor is in communication with the first medium interface, the other end of the first hollow conductor receives the cooling medium, and one end of the second hollow conductor receives the cooling medium.

In some embodiments, the electro-hydraulic separation adapter device further includes a second medium interface, and the one end of the second hollow conductor is in communication with the second medium interface.

In some embodiments, the gradient coil further includes a second connecting conductor and an adapter device, wherein the one end of the second hollow conductor is connected to the adapter device, the adapter device receives the cooling medium from a cooling device, one end of the second connecting conductor is electrically connected to the one end of the second hollow conductor by the adapter device, and the other end of the second connecting conductor is electrically connected to the first connecting conductor.

In some embodiments, each of the plurality of hollow conductors is connected to a cooling device, one end of each of the plurality of hollow conductors receives the cooling medium output from a cooling device, and the other end of the each of the plurality of hollow conductors delivers the cooling medium to the cooling device.

In some embodiments, each of the plurality of hollow conductors includes a first end and a second end, each of the plurality of hollow conductors is wound in a spiral shape either from the inside out or from the outside in, the first end is an end located at a center of the spiral shape, and the second end is an end located at an outer side of the spiral shape, and the electro-hydraulic separation adapter device is located at the first end, or the electro-hydraulic separation adapter device is located at the second end.

In some embodiments, each of the plurality of conductor structures includes a plurality of coil units, and a last one of the plurality of hollow conductors of one of the plurality of coil units is connected to a first one of the plurality of hollow conductors of another one of the plurality of coil units.

In some embodiments, the plurality of coil units include a first coil unit and a second coil unit, the first coil unit includes a first transmission conductor connected to the plurality of hollow conductors, the second coil unit includes a second transmission conductor connected to the plurality of hollow conductors, and the first transmission conductor and the second transmission conductor are led out from different ends of the gradient coil along an axial direction of the gradient coil.

In some embodiments, the plurality of conductor structures include two conductor structures spaced apart from each other, wherein the two conductor structures are spaced apart along a circumferential direction of the gradient coil, and a spacing between the two conductor structures forms a lead-out slot.

In some embodiments, the gradient coil further includes a transmission conductor assembly connected to the plurality of hollow conductors, the first transmission conductor assembly is disposed in the lead-out slot.

One or more embodiments of the present disclosure provide a gradient coil. The gradient coil includes a first hollow conductor and a second hollow conductor, wherein the first hollow conductor and the second hollow conductor form concentric loops, the a first hollow conductor includes a first conduit for a cooling medium to flow through, the second hollow conductor includes a second conduit for the cooling medium to flow through, the first conduit and the second conduit form a parallel cooling circuit.

In some embodiments, the first hollow conductor and the second hollow conductor are connected in series in a circuit.

In some embodiments, the gradient coil further includes one or more coil units, wherein each of the one or more coil units is cooled via the first conduit and the second conduit.

In some embodiments, a length of each of the first conduit and the second conduit is less than a total length of the concentric loops formed by the first hollow conductor and the second hollow conductor.

In some embodiments, one end of each of the first hollow conductor and the second hollow conductor receives a cooling medium from a cooling device, and the other end of each of the first hollow conductor and the second hollow conductor delivers the cooling medium to the cooling device.

One or more embodiments of the present disclosure provide a magnetic resonance imaging (MRI) device. The magnetic resonance imaging device includes a gradient coil, wherein the gradient coil includes a plurality of conductor structures, each of the plurality of conductor structures includes one or more coil units wound in a concentric manner, each of the one or more coil units includes a plurality of hollow conductors, and a conduit for a cooling medium to pass through is disposed within each of the plurality of hollow conductors, the plurality of hollow conductors are connected in series in a circuit, and at least two conduits of the plurality of hollow conductors are connected in parallel.

### BRIEF DESCRIPTION OF THE DRAWINGS

The present disclosure will be further illustrated by way of exemplary embodiments, which will be described in detail through the accompanying drawings. These embodiments are not limiting. In these embodiments, the same reference numerals denote the same structures, FIG. 1 is a schematic diagram illustrating a cross-sectional structure of an exemplary gradient coil according to some embodiments of the present disclosure;

FIG. 2 is a schematic diagram illustrating a three-dimensional structure of an exemplary conductor structure according to some embodiments of the present disclosure;

FIG. 3 is a schematic diagram illustrating a cross-sectional structure of exemplary hollow conductors according to some embodiments of the present disclosure;

FIG. 4 is a schematic diagram illustrating a partial three-dimensional structure of an exemplary gradient coil according to some embodiments of the present disclosure;

FIG. 5 is a schematic diagram illustrating a planar unfolded structure of an exemplary conductor structure according to some embodiments of the present disclosure;

FIG. 6 is another schematic diagram illustrating a planar unfolded structure of an exemplary conductor structure according to some embodiments of the present disclosure;

FIG. 7 is another schematic diagram illustrating a planar unfolded structure of an exemplary conductor structure according to some embodiments of the present disclosure;

FIG. 8 is a schematic diagram illustrating a cross-sectional structure of an exemplary electro-hydraulic separation adapter device when not inserted into hollow conductors according to some embodiments of the present disclosure;

FIG. 9 is a schematic diagram illustrating a cross-sectional structure of an exemplary electro-hydraulic separation adapter device when inserted into hollow conductors according to some embodiments of the present disclosure;

FIG. 10 is a schematic diagram illustrating a cross-sectional structure of an exemplary adapter device according to some embodiments of the present disclosure;

FIG. 11 is a schematic diagram illustrating an exemplary structure of an input adapter device or an output adapter device according to some embodiments of the present disclosure;

FIG. 12 is a schematic diagram illustrating a partial three-dimensional structure of an exemplary coil according to some embodiments of the present disclosure; and

FIG. 13 is a schematic diagram illustrating an exemplary water distribution device according to some embodiments of the present disclosure.

### REFERENCE NUMERALS

1: gradient coil; 10: main coil; 11: X-coil; 111: first lead-out slot; 112: first transmission conductor assembly; 12: Y-coil; 121: second lead-out slot; 13: conductor structure; 13-1: first conductor structure; 13-2: second conductor structure; 13-3: third conductor structure; 13-4: fourth conductor structure; 131: coil unit; 131-1: first coil unit; 131-11: first transmission conductor; 131-2: second coil unit; 131-21: second transmission conductor; 1311: hollow conductor; 1311-1: hollow wire; 1311a: first hollow conductor; 1311b: second hollow conductor; 1311c: third hollow conductor; 1311 d: fourth hollow conductor; 13111: conduit; 13112: tube wall; 132: support component; 14: electro-hydraulic separation adapter device; 14-1: first electro-hydraulic separation adapter device; 14-2: second electro-hydraulic separation adapter device; 141: first medium interface; 142: first connecting conductor; 143: insertion interface; 144: second medium interface; 145-1: first connecting member; 145-2: second connecting member; 145-3: third connecting member; 151-1: second connecting conductor; 151-2: third connecting conductor; 151-3: fourth connecting conductor; 152: input distribution device; 153: outflow collection device; 16: adapter device; 161: terminal; 162: medium channel; 163: interface; 17: input adapter device; 17-1: first input adapter device; 17-2: second input adapter device; 171: first terminal; 172: medium input channel; 173: first interface; 18: output adapter device; 181: second terminal; 182: medium output channel; 183: second interface; 2: cooling device; 20: Z-coil; 210: total water inlet; 220: total water outlet; 230: current inlet; 240: current outlet; 250-1: water inlet connection end; 250-2: water outlet connection end; 30: shielding coil.

### DETAILED DESCRIPTION

To more clearly illustrate the technical solutions of the embodiments of the present disclosure, the drawings used in the description of the embodiments will be briefly introduced below. Obviously, the drawings in the following description are merely some examples or embodiments of the present disclosure. For those of ordinary skill in the art, without creative effort, the present disclosure can be applied to other similar scenarios based on these drawings. Unless obviously obtained from the context or the context illustrates otherwise, the same numeral in the drawings refers to the same structure or operation.

It should be understood that the terms “system”, “device”, “unit”, and/or “module” used herein are methods for distinguishing components, elements, parts, sections, or assemblies of different levels. However, if other words can achieve the same purpose, the words can be replaced by other expressions.

Scientific research in the field of magnetic resonance imaging and applications thereof proposes an increasingly high demand on a performance of a gradient coil. In some embodiments, in a magnetic resonance imaging system, a gradient coil includes three sets of main gradient coils and three sets of shielding gradient coils. The three sets of main gradient coils may be driven by a gradient power amplifier to generate gradient magnetic fields in an X direction, a Y direction, and a Z direction, thereby meeting the imaging requirements of the magnetic resonance imaging system. The three sets of shielding gradient coils may provide shielding gradient magnetic fields in the X direction, the Y direction, and the Z direction, respectively. An X-coil and a Y-coil may be approximately fingerprint-shaped coils, and a Z-coil may be a solenoid coil. The aforementioned six sets of coils can be manufactured as cylindrical structures and coaxially assembled, then encapsulated together with epoxy resin to form a cylindrical gradient coil.

In some embodiments, the gradient coil may be manufactured in the following manner:
winding a conductor on a substrate plane to form a planar coil, fixing the planar coil on a base material plate, and rolling the base material plate with the fixed coil into a cylindrical shape or a semi-cylindrical shape according to requirements. It should be noted that for the manufacturing of the Z-coil among the above coils, a wire winding manner on a cylinder may be adopted.

The performance of the gradient coil may be improved by increasing a count of turns of each coil. In some embodiments, a solid conductor may be used to manufacture the gradient coil. However, using a solid conductor in the gradient coil increases a resistance of the gradient coil and imposes an additional load on a gradient coil current driver.

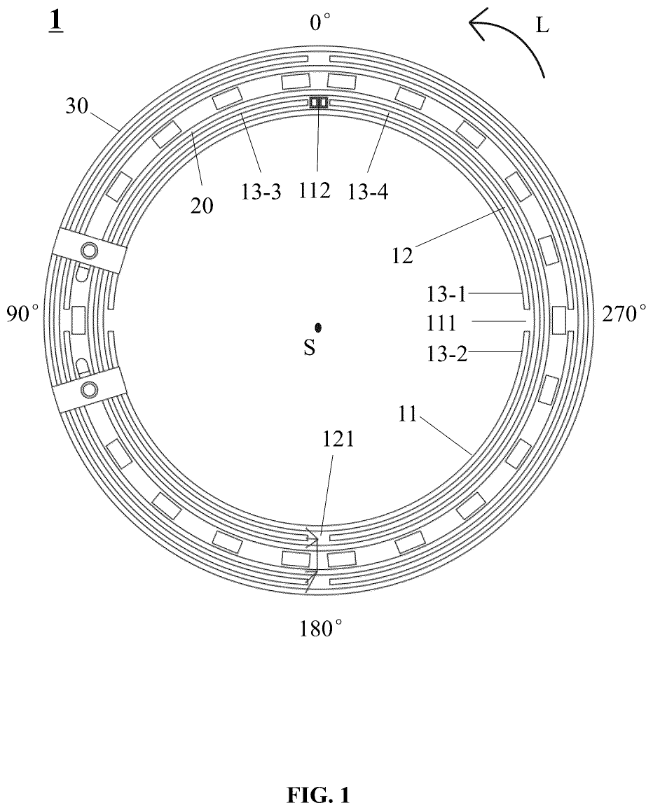

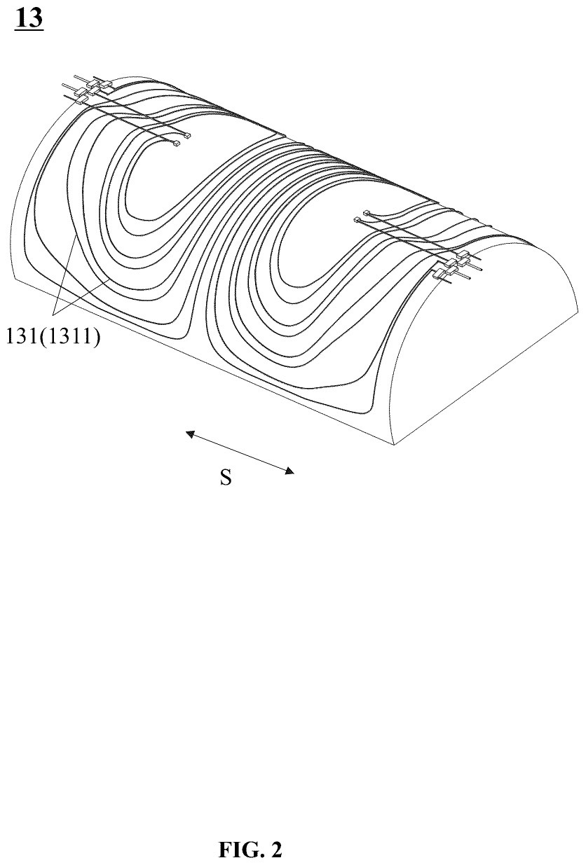

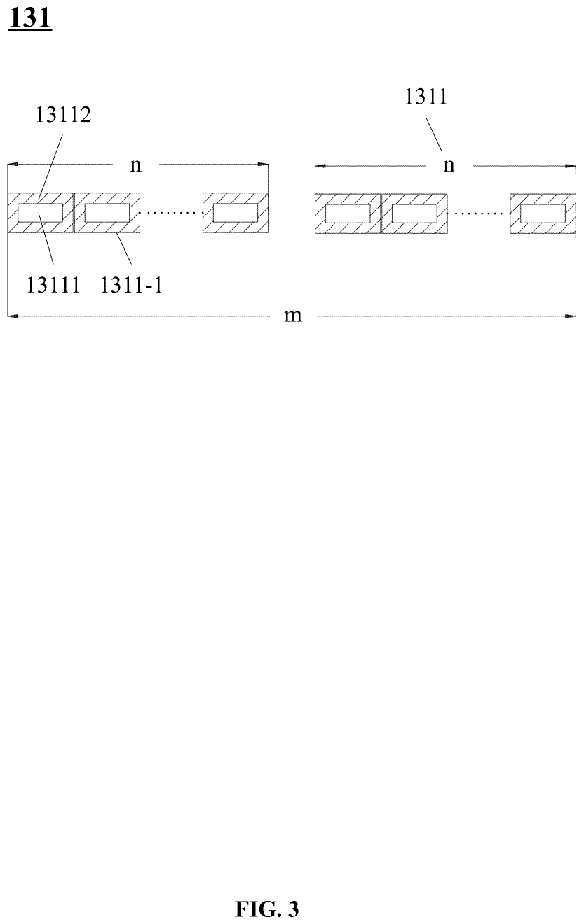

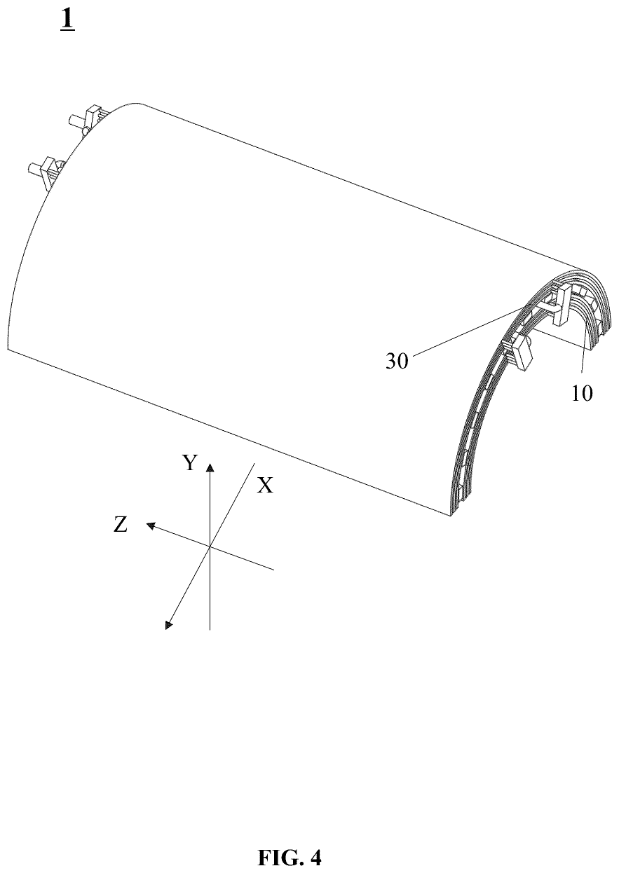

FIG. 1 is a schematic diagram illustrating a cross-sectional structure of an exemplary gradient coil according to some embodiments of the present disclosure; FIG. 2 is a schematic diagram illustrating a three-dimensional structure of an exemplary conductor structure according to some embodiments of the present disclosure; FIG. 3 is a schematic diagram illustrating a cross-sectional structure of exemplary hollow conductors according to some embodiments of the present disclosure; and FIG. 4 is a schematic diagram illustrating a partial three-dimensional structure of an exemplary gradient coil according to some embodiments of the present disclosure.

In some embodiments, as shown in FIG. 1, FIG. 2, and FIG. 3, a gradient coil 1 includes a plurality of conductor structures 13, each of the plurality of conductor structures 13 includes one or more coil units 131 wound in a concentric manner, each of the one or more coil units 131 includes a plurality of hollow conductors 1311, and a conduit 13111 for a cooling medium to pass through is disposed within each of the plurality of hollow conductors 1311.

In some embodiments, the gradient coil 1 includes an X-coil 11 and a Y-coil 12, and at least one of the X-coil 11 and the Y-coil 12 includes the plurality of conductor structures 13. In some embodiments, the gradient coil 1 includes an X-coil 11, a Y-coil 12, and a Z-coil 20, and at least one of the X-coil 11, the Y-coil 12, and the Z-coil includes the plurality of conductor structures 13.

The gradient coil 1 is configured to generate a gradient magnetic field. In some embodiments, as shown in FIG. 1, the gradient coil 1 may be overall presented as a cylindrical structure.

It can be understood that the gradient coil 1 includes three directions: an X-axis, a Y-axis, and a Z-axis, referring to FIG. 4. A coordinate system of a magnetic resonance imaging device and a gradient coil thereof is defined by taking the patient's position as supine and the head first entering the cylindrical structure of the gradient coil 1. An axial direction S of the cylindrical structure (i.e., a direction from the patient's feet to the head) is the Z-axis, and the X-axis and the Y-axis are perpendicular to the Z-axis. The X-axis is in the left-right direction of the human body and points to a left side of an anatomical position. The Y-axis is in an anterior-posterior direction of the human body and points to an anterior side of the anatomical position. One or more sets of gradient coils are arranged on each of the X-axis, the Y-axis, and the Z-axis (i.e., the X-coil 11, the Y-coil 12, and the Z-coil), and the generated gradient magnetic fields are distributed along the corresponding axial direction after the one or more sets of gradient coils are energized.

In some embodiments, as shown in FIG. 4, the gradient coil 1 includes a main coil 10 and a shielding coil 30. The main coil 10 is configured to generate a gradient magnetic field that is linearly distributed in space, and achieve temporal control of the amplitude of the gradient magnetic field through a pulse sequence, so that the precession frequency of nuclei in an imaging region varies with spatial positions thereof, thereby achieving spatial encoding of nuclear signals in an imaging object. The shielding coil 30 is configured to shield external interference, thereby effectively reducing the impact of external electromagnetic waves on internal electronic components, which reduces noise and ensures imaging quality. The shielding coil 30 may be arranged outside the main coil 10, with a gap between the shielding coil 30 and the main coil 10.

In some embodiments, a structure of the main coil 10 and a structure of the shielding coil 30 are the same, and both include the X-coil 11, the Y-coil 12, and a Z-coil 20. A structure of the main coil 10 is taken as an example below to describe a structure of the gradient coil, and descriptions of the shielding coil 30 refers to descriptions of the main coil 10, which do not be repeated.

The X-coil 11 refers to a coil that generates a gradient magnetic field in the X direction when energized. The Y-coil 12 refers to a coil that generates a gradient magnetic field in the Y direction when energized. The Z-coil 20 refers to a coil that generates a gradient magnetic field in the Z direction when energized.

In some embodiments, as shown in FIG. 1, the X-coil 11, the Y-coil 12, and the Z-coil 20 may be arranged sequentially from inside to outside (i.e., the X-coil 11, the Y-coil 12, and the Z-coil 20 are arranged from a surface close to an axis of the cylindrical gradient coil 1 to a direction away from the axis of the cylindrical gradient coil 1). In other embodiments, an arrangement order of the X-coil 11, the Y-coil 12, and the Z-coil 20 may be any other feasible order. For example, a position of the X-coil 11 and a position of the Y-coil 12 may be swapped.

In some embodiments, as shown in FIG. 2, the X-coil 11 or the Y-coil may be approximately a fingerprint-shaped coil. That is, the X-coil 11 or the Y-coil 12 is wound along an arc-shaped path on a curved surface of the cylindrical structure.

The conductor structure 13 refers to a structure in the X-coil 11 and the Y-coil 12 that generates a gradient magnetic field. One or more conductor structures 13 may be provided. One conductor structure 13 may be approximately a fingerprint-shaped coil and wound on the surface of the cylindrical structure. A plurality of conductor structures 13 may include a plurality of fingerprint-shaped coils, each coil of the plurality of coils is wound on the surface of the cylindrical structure, and the plurality of coils may be arranged at intervals along the axial direction S. A structure of a conductor structure in the X-coil 11 and a structure of a conductor structure the Y-coil 12 are the same.

A coil unit 131 is configured to implement an electromagnetic function of a magnetic resonance imaging system. In some embodiments, the coil unit 131 may carry a current and dissipate heat. A count of the coil units 131 is set based on actual demand.

Merely by way of example, a winding trajectory of two coil units 131 is shown in FIG. 2, where current winding directions of the two coil units 131 are opposite, thereby forming a complete conductor structure.

The hollow conductor 1311 refers to a conductor with a hollow internal structure. A hollow conductor 1311 may both conduct electricity with low resistance and guide a flow of the cooling medium, thereby efficiently utilizing space and improving cooling efficiency.

In some embodiments, as shown in FIG. 4, the hollow conductor 1311 includes a tube wall 13112 and a conduit 13111.

The tube wall 13112 is configured to carry the current. In some embodiments, the tube wall 13112 is made of a high conductivity material (e.g., oxygen-free copper, aluminum alloy, etc.).

The conduit 13111 refers to a channel inside the hollow conductor 1311. In some embodiments, the conduit 13111 may be a through hole provided inside the tube wall 13112 for the cooling medium to flow through. The cooling medium is configured to cool the gradient coil 1. In some embodiments, the cooling medium may include one of deionized water, fluorinated liquid, etc. In some embodiments, the cooling medium may flow in the conduit 13111 and carry away heat generated by the tube wall 13112 due to ohmic loss. The conduit 13111 is in communication with an external cooling device 2. The cooling device 2 is configured to supply and recover the cooling medium, and the cooling device 2 uses a supply pipeline for supplying the cooling medium and a recovery pipeline for recovering the cooling medium, respectively. In some embodiments, each of the plurality of hollow conductors 1311 is connected to a cooling device. For example, two hollow conductors 1311 may adopt a parallel topology, and there is no series-connected fluid communication path between them, and the two hollow conductors 1311 (sharing a common or independent cooling source) may supply the cooling device independently for cooling.

In some embodiments, each of the one or more coil units 131 includes a plurality of turns of hollow conductors 1311 that are in a spatially parallel arrangement. Two turns, three turns, four turns, seven turns, or more turns of the hollow conductors 1311 may be provided. The plurality of turns of hollow conductors 1311 that are in a spatially parallel arrangement may be understood as: the plurality of turns of hollow conductors 1311 being arranged side by side in space, and being spirally wound along a preset trajectory around a common axis and on a same plane. Any pair of turns of the plurality of turns of hollow conductors 1311 are spirally wound along substantially similar trajectories, but are not necessarily parallel.

In some embodiments, each of the plurality of hollow conductors 1311 includes a plurality of hollow wires 1311-1. In some embodiments, each of the plurality of hollow wires 1311-1 includes the tube wall 13112 and the conduit 13111 enclosed by the tube wall 13112. In some embodiments, a cross-section of each of the plurality of hollow wires 1311-1 may be circular, flat, rectangular, or any other shape. The cross-section refers to a plane perpendicular to an extending direction of the each of the plurality of hollow wires 1311-1.

Merely by way of example, as shown in FIG. 3, each of the one or more coil units 131 includes m turns of hollow conductors 1311 that are in a spatially parallel arrangement, each turn of m turns of the hollow conductors 1311 includes n hollow wires 1311-1, and each turn of m turns of the hollow conductor 1311 may be spirally wound along a preset winding trajectory (e.g., the winding trajectory in FIG. 2). A value of m and a value of n are determined based on actual demand.

In some embodiments of the present disclosure, the gradient coil made by using the plurality of hollow conductors with a hollow conduit, both achieves low-resistance electrical conduction and provides conduits for transporting the cooling medium, which not only utilizes space more efficiently, but also improves cooling efficiency, thereby enabling generation of a high-performance gradient magnetic field with a small current, and further ensuring functional requirements of the gradient coil.

A manner of spirally winding the coil from start to finish using one hollow conduit, may result in a relatively long transport path for the current and the cooling medium, and a single flow of the cooling medium needs to flow through the entire spiral winding path. However, the flow of the cooling medium is affected by factors such as friction, resistance, and flow resistance, etc., which leads to fluid loss, reduced velocity, energy loss, etc., thereby reducing cooling efficiency. When the fluid passes through the hollow conduit, a water pressure value gradually decreases as the pipe length increases, which further reduces the cooling efficiency, and makes it difficult to meet the design requirements for the ultra-high performance gradient coil. Therefore, there is a need to optimize the transport paths for the current and the cooling medium.

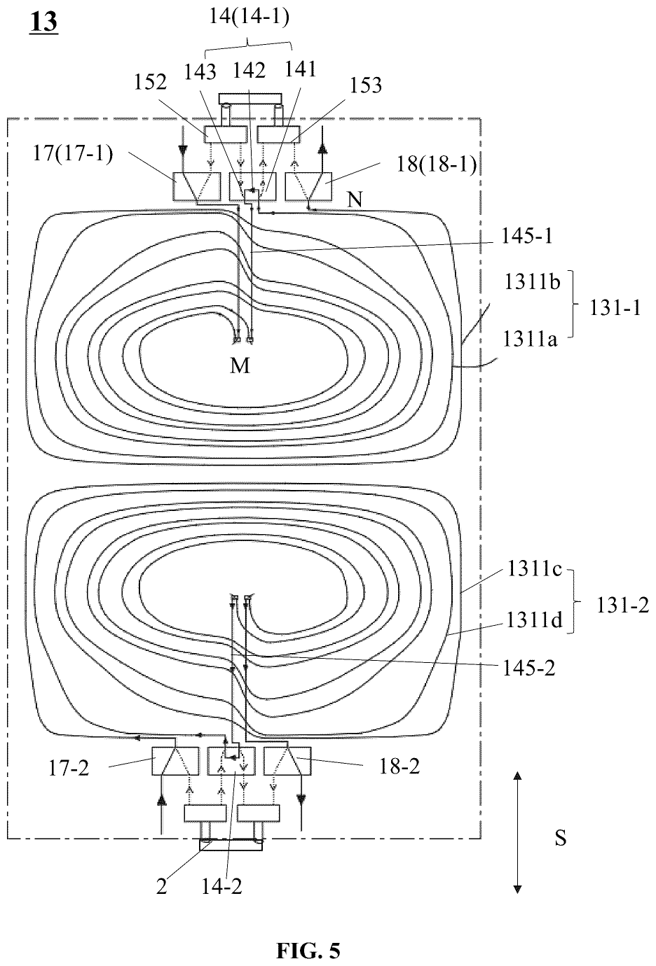

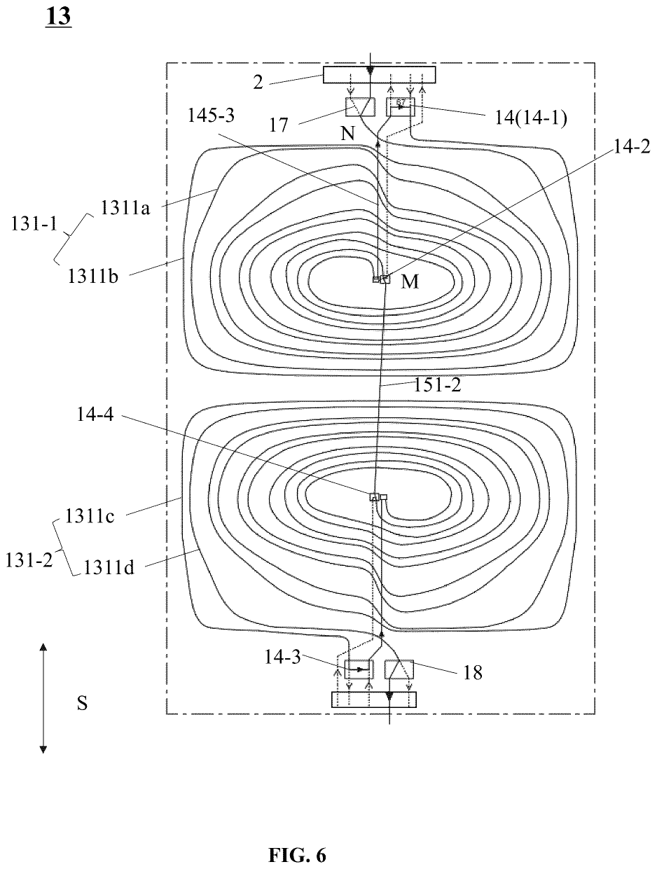

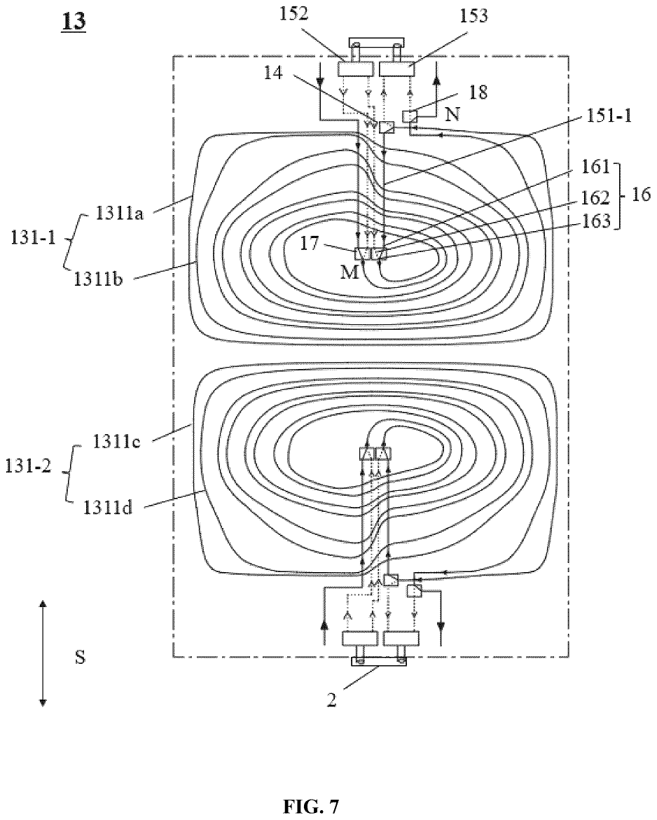

FIG. 5 is a schematic diagram illustrating a planar unfolded structure of an exemplary conductor structure according to some embodiments of the present disclosure; FIG. 6 is another schematic diagram illustrating a planar unfolded structure of an exemplary conductor structure according to some embodiments of the present disclosure; and FIG. 7 is another schematic diagram illustrating a planar unfolded structure of an exemplary conductor structure according to some embodiments of the present disclosure.

In some embodiments, as shown in FIGS. 5-7, a plurality of hollow conductors are connected in series in a circuit, and at least two conduits of the plurality of hollow conductors are connected in parallel.

The circuit refers to a path for current to flow through. The circuit may be a current closed loop in series formed by the plurality of hollow conductors 1311 and other electrical connection devices (e.g., an electro-hydraulic separation adapter device 14, an external power supply, etc.).

In some embodiments, connecting the circuit in series may be understood as follow. A current may be input from an input end of a first turn of hollow conductor 1311, output from an output end of the first turn of hollow conductor 1311 to input to an input end of a second turn of hollow conductor 1311, and then input to a third turn of hollow conductor 1311 sequentially in the above manner and so on, until output from an output end of an m-th turn of hollow conductor 1311. That is, the m turns of hollow conductors 1311 are collectively regarded as one closed loop for current transmission. The first turn, the second turn, . . . , the m-th turn may represent an order in which the current flows, i.e., the current flows sequentially through the first turn, the second turn, . . . , the m-th turn. In other embodiments, the order in which the current flows may also be the m-th turn, the (m−1)-th turn . . . the second turn, the first turn.

In some embodiments, connecting the conduits 13111 in parallel may be understood as follow. The cooling medium may be simultaneously input from input ends of the first turn of hollow conductor 1311, the second turn of hollow conductor 1311, . . . , and the m-th turn of hollow conductor 1311, and output from output ends of the first turn of hollow conductor 1311, the second turn of hollow conductor 1311, . . . , and the m-th turn of hollow conductor 1311. That is, each turn of the plurality of turns of hollow conductors 1311 may be regarded as one closed loop for cooling medium transmission, so that the cooling medium simultaneously flows into inlets of the conduits of the plurality of hollow conductors 1311, and flows out from outlets of the conduits of the plurality of hollow conductors 1311.

In some embodiments, a configuration of series-connected circuits and the spatially parallel arrangement of water paths is formed by setting electro-hydraulic separation adapter devices in the gradient coil. The first transmission conductor assembly of the X-coil in the gradient coil is located at a gap position (e.g., the second lead-out slot) of the Y-coil. The second transmission conductor assembly is located at the gap position (e.g., the first lead-out slot) of the X-coil.

Under the premise of unchanged performance of the gradient coil, the gap size of the gradient coil is fixed. The more pipelines and/or lines of the first transmission conductor assembly or the second transmission conductor assembly the gap can accommodate, the shorter the water path and the higher the cooling efficiency.

For the scheme where each of the X coil and the Y coil include two coil units, if the transmission conductor components are led out from one end, the two coil units placed inside the corresponding transmission conductor components needs to be considered when designing the gap width. Compared with the transmission conductor components of the two coil units led out from one end, at the same gap width, there is twice as much space to set up the transmission conductor components by causing the transmission conductor components of the two coil units to be led out from both ends. In the embodiments described in the present disclosure, the formation of parallel-connected water paths can shorten the path of the cooling medium, which also means that there are more pipelines and/or lines (solid and/or hollow) in the transmission conductor components. By leading out the transmission conductor components from both ends, there is more space to set up the transmission conductor components in the gap, which allows more pipelines and/or lines to have placement space without increasing the size of the gap, thus eliminating the need to increase the size of the gap at the expense of the performance of the gradient coil. Based on this, the embodiments of the present disclosure include two coil units, and each coil unit includes two hollow conductors, and a parallel water circuit scheme. Compared with the scheme of parallel-connected water paths and transmission conductor components led out from one end, the heat dissipation effect is greatly improved. After testing, the heat dissipation effect of the scheme in the present disclosure has been improved by 70%. Moreover, the performance of the gradient coil has not been sacrificed, the heat dissipation effect has been improved, and the duty cycle of the gradient coil can be increased, thereby increasing the equivalent direct current gradient strength. After testing, the equivalent direct current gradient strength in the embodiments of the present disclosure can be increased by more than 30%.

In some embodiments of the present disclosure, the manner of connecting the circuit in series and connecting the conduits in parallel can shorten the winding path of the cooling medium, thereby significantly improving the cooling efficiency.

In some embodiments, as shown in FIGS. 5-7, the gradient coil 1 includes one or more electro-hydraulic separation adapter devices 14, wherein each of the one or more electro-hydraulic separation adapter devices 14 effects a series circuit connection between a pair of the plurality of hollow conductors 1311, the electro-hydraulic separation adapter device 14 leads out the cooling medium from a conduit 13111 of one of the pair of the plurality of hollow conductors 1311.

In other embodiments, the electro-hydraulic separation adapter device 14 leads out the cooling medium from the conduit 13111 of one of the pair of the plurality of hollow conductors 1311, and the electro-hydraulic separation adapter device 14 introduces the cooling medium into the other of the pair of the plurality of hollow conductors 1311.

The electro-hydraulic separation adapter device 14 is configured to transmit the current and export the cooling medium. In some embodiments, the electro-hydraulic separation adapter device 14 may also be configured to receive the cooling medium provided by the cooling device 2 and provide the cooling medium to the plurality of hollow conductors 1311. In some embodiments, the electro-hydraulic separation adapter device 14 is connected to a pair of hollow conductors 1311 and the cooling device 2, respectively.

In some embodiments, the pair of hollow conductors 1311 are connected in series via the electro-hydraulic separation adapter device 14, and the electro-hydraulic separation adapter device 14 leads out the cooling medium from a preceding one of the pair of hollow conductors 1311 connected thereto to the cooling device 2. Understandably, the cooling medium from the cooling device 2 may be directly introduced into a subsequent one of the pair of hollow conductors 1311 without being introduced through the electro-hydraulic separation adapter device 14. The preceding one refers to a turn of the pair of hollow conductors 1311 connected to the electro-hydraulic separation adapter device 14 through which current flows first, and the subsequent one refers to a turn of the pair of hollow conductors 1311 connected to the electro-hydraulic separation adapter device 14 through which current flows later.

In some other embodiments, the pair of hollow conductors 1311 are connected in series in the circuit through the electro-hydraulic separation adapter device 14. The electro-hydraulic separation adapter device 14 leads out the cooling medium from the preceding one of hollow conductor 1311 connected thereto to the cooling device 2, and introduces the cooling medium from the cooling device 2 into the subsequent one of hollow conductor 1311.

The following further illustrates using a pair of the plurality of hollow conductors 1311 as an example. As shown in FIG. 5, the current may be input from a current input end of the first turn of hollow conductor 1311 (i.e., a first hollow conductor 1311a shown in FIG. 5), output from a current output end of the first turn of hollow conductor 1311 to the electro-hydraulic separation adapter device 14, then input from the electro-hydraulic separation adapter device 14 to a current input end of the second turn of hollow conductor 1311 (i.e., a second hollow conductor 1311b shown in FIG. 5), and then output from a current output end of the second turn of hollow conductor 1311, thereby achieving the series circuit connection of the pair of turns of hollow conductors 1311. The cooling medium may be input from the cooling device 2 into the first turn of hollow conductor 1311 and the second turn of hollow conductor 1311 respectively, the cooling medium is led out from the first turn of hollow conductor 1311 through the electro-hydraulic separation adapter device 14, and the cooling medium is led out from the second turn of hollow conductor 1311, thereby achieving the spatially parallel arrangement of the conduits.

In some embodiments of the present disclosure, by providing the electro-hydraulic separation adapter device, the series circuit connection and the spatially parallel arrangement of the conduits may be achieved, thereby shortening the winding path of the cooling medium and improving cooling efficiency.

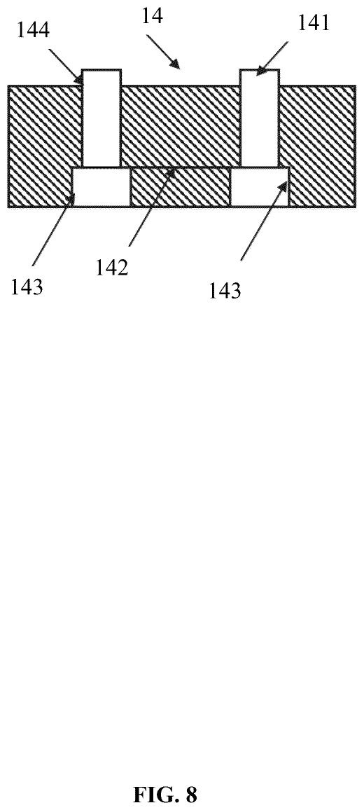

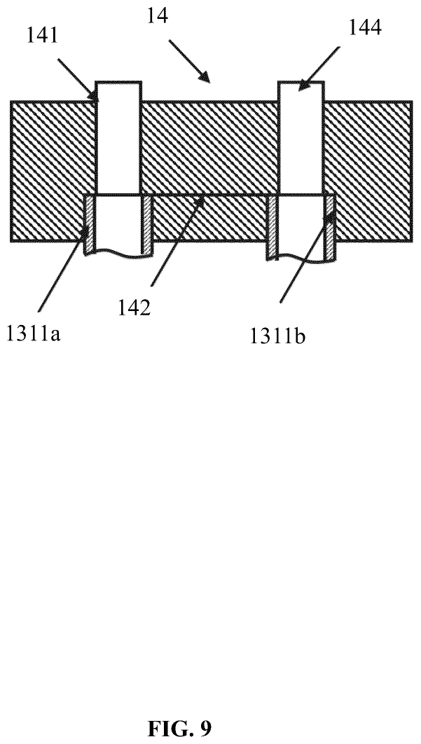

More specific descriptions is provided below in conjunction with a structure of the electro-hydraulic separation adapter device 14. FIG. 8 is a schematic diagram illustrating a cross-sectional structure of an exemplary electro-hydraulic separation adapter device when not inserted into hollow conductors according to some embodiments of the present disclosure; and FIG. 9 is a schematic diagram illustrating a cross-sectional structure of an exemplary electro-hydraulic separation adapter device when inserted into hollow conductors according to some embodiments of the present disclosure.

In some embodiments, as shown in FIG. 5 to FIG. 9, the electro-hydraulic separation adapter device 14 includes a first medium interface 141 and a first connecting conductor 142, the coil unit 131 includes the first hollow conductor 1311a and the second hollow conductor 1311b, one end of the first hollow conductor 1311a is connected to the electro-hydraulic separation adapter device 14, one end of the first hollow conductor 1311a and one end of the second hollow conductor 1311b are electrically connected by the first connecting conductor 142, one end of the first hollow conductor 1311a is in communication with the first medium interface 141, the other end of the first hollow conductor 1311a receives the cooling medium, and one end of the second hollow conductor 1311b receives a cooling medium. It should be noted that the first hollow conductor 1311a and the second hollow conductor 1311b refer to a pair of hollow conductors connected via the electro-hydraulic separation adapter device 14, whereas the first turn of hollow conductor 1311 and the second turn of hollow conductor 1311 are defined based on an order of current flow.

The first medium interface 141 is configured to lead out the cooling medium. In some embodiments, one end of the first medium interface 141 is in communication with a conduit of the first hollow conductor 1311a, the other end of the first medium interface 141 is in communication with a recovery pipeline of the cooling device 2, and the cooling medium in the conduit of the first hollow conductor 1311a may be output to the cooling device 2 through the first medium interface 141. “In communication with” may be understood as: internal spaces (i.e., the conduits) of two structures being continuous, i.e., the cooling medium can flow within the internal spaces of the two structures.

The first connecting conductor 142 is configured to achieve electrical connection between the first hollow conductor 1311a and the second hollow conductor 1311b. In some embodiments, the first connecting conductor 142 may be made of a high conductivity material (e.g., oxygen-free copper, aluminum alloy, etc.).

In some embodiments, the first hollow conductor 1311a and the second hollow conductor 1311b may be respectively connected with connecting members capable of connecting to the electro-hydraulic separation adapter device 14, and the connecting members with same shape and material as the hollow conductor 1311, may be electrically connected to the first hollow conductor 1311a and the second hollow conductor 1311b and in communication with conduits 13111 of the first hollow conductor 1311a and the second hollow conductor 1311b. As shown in FIG. 8, the electro-hydraulic separation adapter device 14 is provided with two insertion interfaces 143. In some embodiments, as shown in FIG. 9, shapes and sizes of the two insertion interfaces 143 are adapted to shapes and sizes of the first hollow conductor 1311a and the second hollow conductor 1311b and the connecting members thereof, respectively, so that the first hollow conductor 1311a and the second hollow conductor 1311b may be connected to the insertion interfaces 143 either directly or via the two connecting members. For example, as shown in FIG. 5, a first connecting member 145-1 and the second hollow conductor 1311b are inserted into two insertion interfaces 143 of an electro-hydraulic separation adapter device 14-1, respectively. As another example, as shown in FIG. 6, a second connecting member 145-2 and a fourth hollow conductor 1311d are inserted into two insertion interfaces 143 of the electro-hydraulic separation adapter device 14-2, respectively.

In some embodiments, two ends of the first connecting conductor 142 are disposed on side walls of the two insertion interfaces 143. Thus, the first connecting conductor 142 contacts the first hollow conductor 1311a (or a connecting member thereof) and the second hollow conductor 1311b (or a connecting member thereof) respectively after the first hollow conductor 1311a and the second hollow conductor 1311b are connected to the two insertion interfaces 143, enabling current conduction between the first hollow conductor 1311a and the second hollow conductor 1311b.

In some embodiments, as shown in FIG. 5 to FIG. 6 and FIG. 8 to FIG. 9, the electro-hydraulic separation adapter device 14 further includes a second medium interface 144, one end of the second hollow conductor 1311b is connected to the electro-hydraulic separation adapter device 14, and one end of the second hollow conductor 1311b is in communication with the second medium interface 144. Understandably, the electro-hydraulic separation adapter device 14 may be used only to lead out the cooling medium from one of the pair of hollow conductors 1311 connected thereto, and in this case, the electro-hydraulic separation adapter device 14 does not include the second medium interface 144.

The second medium interface 144 is configured to introduce the cooling medium. In some embodiments, one end of the second medium interface 144 is in communication with a conduit of the second hollow conductor 1311b, and the other end of the second medium interface 144 is in communication with a supply pipeline of the cooling device 2. It is understood that the flow direction of the cooling medium is not limited to the direction shown in the drawings. For example, the first medium interface can be configured to introduce the cooling medium, and the second medium interface can be configured to lead out the cooling medium.

Merely by way of example, as shown in FIG. 5, FIG. 6, FIG. 8, and FIG. 9, when the first hollow conductor 1311a and the second hollow conductor 1311b are respectively connected to the two insertion interfaces 143, the conduits 13111 of the first hollow conductor 1311a and the second hollow conductor 1311b are in communication with the first medium interface 141. The cooling medium in the conduit 13111 of the first hollow conductor 1311a may be output to the cooling device 2 through the first medium interface 141, and the cooling medium from the cooling device 2 may be input into the conduit 13111 of the second hollow conductor 1311b through the second medium interface 144, thereby achieving spatially parallel arrangement of the conduits of the first hollow conductor 1311a and the second hollow conductor 1311b. Furthermore, the first hollow conductor 1311a and the second hollow conductor 1311b may be conductively contacted through the first connecting conductor 142, so that the current may flow from the first hollow conductor 1311a to the second hollow conductor 1311b through the first connecting conductor 142, thereby achieving series circuit connection of the first hollow conductor 1311a and the second hollow conductor 1311b.

In some embodiments of the present disclosure, by providing the first medium interface and the first connecting conductor in the electro-hydraulic separation adapter device, the series circuit connection and the spatially parallel arrangement of the conduits of the first hollow conductor and the second hollow conductor can be achieved, thereby shortening the winding path of the cooling medium and improving cooling efficiency. Furthermore, the second medium interface is provided to ensure that the cooling medium introduced into the conduit of the hollow conductor is unused cooling medium, further ensuring the cooling effect.

In some embodiments, a connection channel may be provided between the first medium interface 141 and the second medium interface 144, and a three-way valve may be provided at the connection between the first medium interface 141 and the connection channel. When the three-way valve is in communication with the first medium interface 141 and closes the connection channel, the conduits of the first hollow conductor 1311a and the second hollow conductor 1311b are connected in parallel. When the three-way valve closes the first medium interface 141 and is in communication with the connection channel, the second medium interface 141 may not input the cooling medium, the cooling medium from the first hollow conductor 1311a is input into the second hollow conductor 1311b through the connection channel, i.e., series connection of the conduits of the first hollow conductor 1311a and the second hollow conductor 1311b is achieved. Such a configuration enables switching between different operating modes, and selective switching between parallel and series connection of the conduits of the first hollow conductor 1311a and the second hollow conductor 1311b may be achieved using only the electro-hydraulic separation adapter device, which improves applicability. Understandably, the three-way valve is a manually controlled valve or an electrically controlled valve.

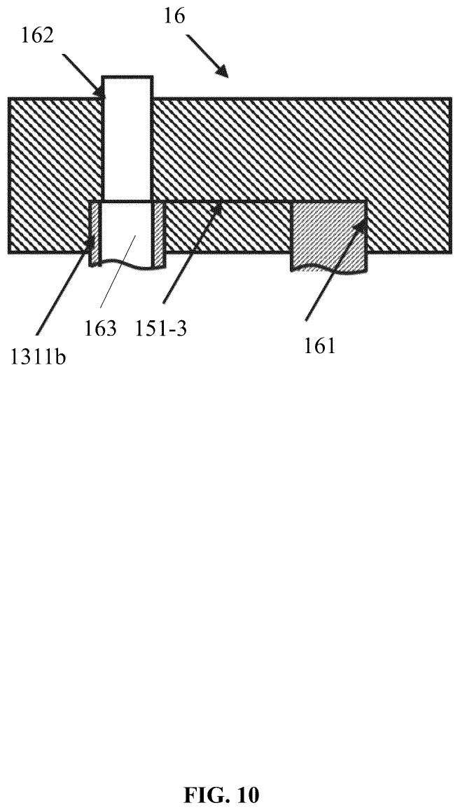

FIG. 10 is a schematic diagram illustrating a cross-sectional structure of an exemplary adapter device according to some embodiments of the present disclosure.

In some embodiments, as shown in FIG. 7 and FIG. 10, the gradient coil 1 further includes a second connecting conductor 151-1 and an adapter device 16, wherein the one end of the second hollow conductor 1311b is connected to the adapter device 16, the adapter device 16 receives the cooling medium from the cooling device 2, one end of the second connecting conductor 151-1 is electrically connected to the one end of the second hollow conductor 1311b by the adapter device 16, and the other end of the second connecting conductor 151-1 is electrically connected to the first connecting conductor 142.

In some embodiments, the adapter device 16 includes a terminal 161, a medium channel 162, and an interface 163; the interface 163 is configured to connect to one end of the second hollow conductor 1311b, the medium channel 162 receives a cooling medium output from the cooling device 2, the terminal 162 is electrically connected to one end of the second connecting conductor 151-1, one end of the second connecting conductor 151-1 is electrically connected to one end of the second hollow conductor 1311b, the medium channel 162 is in communication with a conduit 13111 of one end of the second hollow conductor 1311b, and the other end of the second connecting conductor 151-1 is electrically connected to the first connecting conductor 142.

The second connecting conductor 151-1 is configured to achieve electrical connection between the first hollow conductor 1311a and the second hollow conductor 1311b. In some embodiments, the second connecting conductor 151-1 may be a hollow or solid wire. In some embodiments, the second connecting conductor 151-1 may be made of a high conductivity material. In some embodiments, one end of the second connecting conductor 151-1 is connected to the adapter device 16, and the other end is connected to the first connecting conductor 142 of the electro-hydraulic separation adapter device 14. In some embodiments, the second connecting conductor 151-1 may be inserted into the insertion interface 143 of the electro-hydraulic separation adapter device 14.

The adapter device 16 is configured to cooperate with the electro-hydraulic separation adapter device 14 to introduce the cooling medium into the second hollow conductor 1311b and conduct current. In some embodiments, one end of the adapter device 16 is connected to the second connecting conductor 151-1, and the other end is connected to the second hollow conductor 1311b.

The terminal 161 is configured to connect to the second connecting conductor 151-1 to achieve electrical connection between the second connecting conductor 151-1 and the second hollow conductor 1311b. In some embodiments, the terminal 161 may be made of a high conductivity material. In some embodiments, the terminal 161 and the second hollow conductor 1311b may be electrically connected through a fourth connecting conductor 151-3.

The medium channel 162 is configured to convey the cooling medium to the second hollow conductor 1311b. In some embodiments, one end of the medium channel 162 is connected to a supply pipeline of the cooling device 2, and the other end is in communication with a conduit of the second hollow conductor 1311b, and the cooling medium from the cooling device 2 may be conveyed to the second hollow conductor 1311b through the medium channel 162.

The interface 163 is configured to insert the second hollow conductor 1311b. In some embodiments, a shape and a size of the interface 163 are adapted to a shape and a size of the second hollow conductor 1311b.

Merely by way of example, as shown in FIG. 7 and FIG. 10, the cooling medium of the first hollow conductor 1311a is output to the cooling device 2 through the electro-hydraulic separation adapter device 14. When the second hollow conductor 1311b is inserted into the interface 163, the medium channel 162 is in communication with the conduit 13111 of the second hollow conductor 1311b, and the cooling medium in the cooling device 2 may be conveyed to the conduit 13111 of the second hollow conductor 1311b through the medium channel 162, so as to achieve the spatially parallel arrangement of the conduits of the first hollow conductor 1311a and the second hollow conductor 1311b. Simultaneously, since the second hollow conductor 1311b is inserted into the interface 163, the second hollow conductor 1311b is capable of electrically connecting with the terminal 161. The terminal 161 is connected to one end of the second connecting conductor 151-1. The other end of the second connecting conductor 151-1 is connected to the first hollow conductor 1311a. Thus, a series circuit connection of the first hollow conductor 1311a and the second hollow conductor 1311b is achieved.

In some embodiments of the present disclosure, the adapter device and the second connecting conductor are provided to achieve the series circuit connection and the spatially parallel arrangement of the conduits of the hollow conductors, thereby shortening winding path of the cooling medium and improving cooling efficiency.

In some embodiments, each of the plurality of hollow conductors 1311 is connected to the cooling device 2, that is, different hollow conductors 1311 are each separately coupled to the cooling device 2, so as to individually receive and deliver the cooling medium from the cooling device 2.

In some embodiments, as shown in FIG. 5 to FIG. 7, one end of each of the plurality of hollow conductors 1311 receives the cooling medium output from the cooling device 2. The other end of each of the plurality of hollow conductors 1311 conveys the cooling medium to the cooling device 2.

More descriptions regarding the cooling device 2 may be found in the foregoing. Merely by way of example, the cooling device 2 may be a circulating cooling water device.

In some embodiments, the supply pipeline of the cooling device 2 is in communication with a plurality of input interfaces (e.g., the second medium interface 144 of a plurality of electro-hydraulic separation adapter devices 14, a medium input channel 172, etc.) for inputting the cooling medium into the hollow conductor 1311, and a recovery pipeline of the cooling device 2 is in communication with a plurality of output interfaces (e.g., the first medium interface 141 of the plurality of electro-hydraulic separation adapter devices 14, a medium output channel 182, etc.) for outputting the cooling medium from the hollow conductor 1311. One end of each of hollow conductor 1311 may receive the cooling medium output from the cooling device 2 through a corresponding input interface, and the other end of each of hollow conductor 1311 may convey the cooling medium to the cooling device 2 through a corresponding output interface. More descriptions regarding the medium input channel 172 and the medium output channel 182 may be found in descriptions in FIG. 9.

In some embodiments of the present disclosure, by providing the cooling device, the cooling medium can be recycled inside the gradient coil.

In some embodiments, a water distribution device is installed between the cooling device 2 and a plurality of hollow conductors 1311.

In some embodiments, as shown in FIG. 5 and FIG. 7, the water distribution device includes an input distribution device 152 and an outflow collection device 153.

The input distribution device 152 is configured to distribute the cooling medium from the cooling device 2 to corresponding conduits of the plurality of hollow conductors 1311. In some embodiments, the input distribution device 152 includes a first inflow pipeline in communication with the cooling device 2 and a plurality of first outflow pipelines, wherein the plurality of first outflow pipelines are respectively connected to the plurality of input interfaces for inputting the cooling medium into the plurality of hollow conductors 1311.

The outflow collection device 153 is configured to collect the cooling medium respectively output from the plurality of hollow conductors 1311. In some embodiments, the outflow collection device 153 includes a plurality of second inflow pipelines and a second outflow pipeline in communication with the cooling device 2, wherein the plurality of second inflow pipelines are respectively connected to the plurality of output interfaces for outputting the cooling medium from the hollow conductor 1311.

In some embodiments, the input distribution device 152 and the outflow collection device 153 may be made of a thermally conductive material, thereby further improving cooling efficiency while achieving water distribution.

It is understandable that the cooling medium in the main coil 10 and the shielding coil 30 may flow into and out of the corresponding input distribution device 152 and outflow collection device 153 respectively through the same water distribution device.

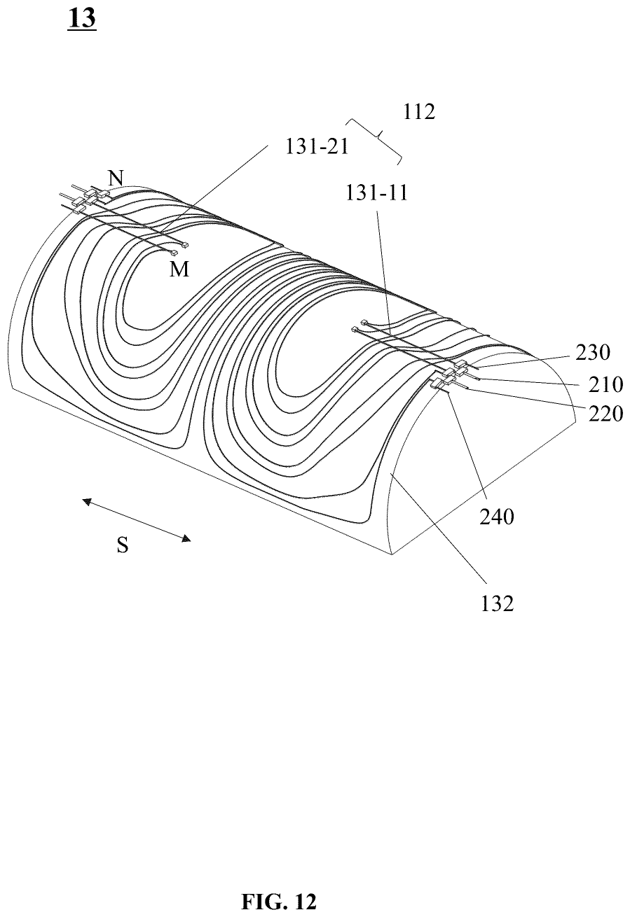

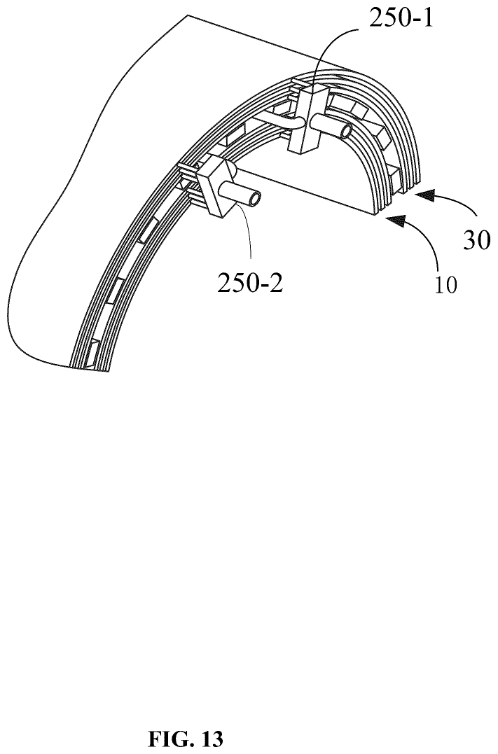

More descriptions regarding the water distribution device may be found in FIG. 12 and FIG. 13 and related descriptions thereof.

In some embodiments of the present disclosure, the water distribution device is provided to facilitate connection and maintenance replacement of pipelines, and improve overall operating efficiency of the device.

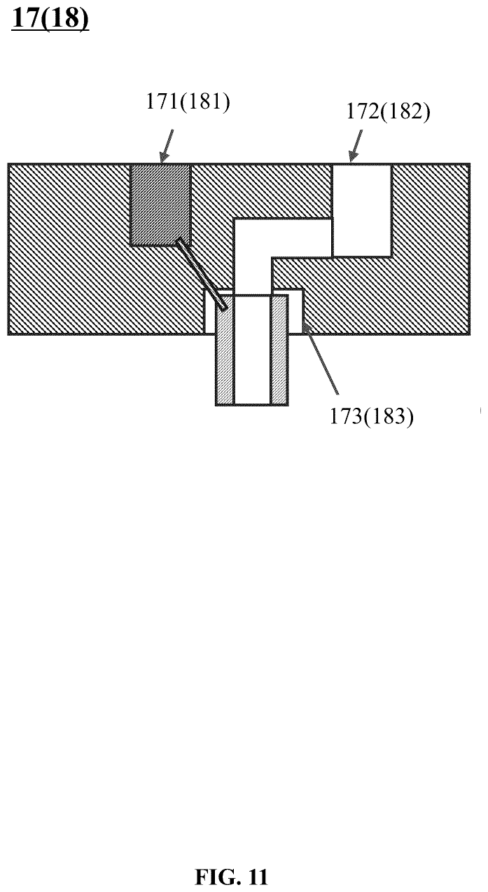

FIG. 11 is a schematic diagram illustrating an exemplary structure of an input adapter device or an output adapter device according to some embodiments of the present disclosure.

In some embodiments, as shown in FIG. 5 and FIG. 11, the gradient coil 1 further includes an input adapter device 17 and an output adapter device 18. The input adapter device 17 includes a first terminal 171, a medium input channel 172, and a first interface 173. The medium input channel 172 receives the cooling medium output from the cooling device 2. The first interface 173 is configured to connect to one end of a first turn of the plurality of turns of hollow conductors 1311. The first terminal 171 is electrically connected to the one end of the first turn of the plurality of turns of hollow conductors 1311, and the medium input channel 172 is in communication with a conduit of the one end of the first turn of the plurality of turns of hollow conductors 1311. The output adapter device 18 includes a second terminal 181, a medium output channel 182, and a second interface 183. The second interface 183 is configured to connect to a last turn of the plurality of turns of hollow conductors 1311. The medium output channel 182 delivers the cooling medium to the cooling device 2. The second terminal is electrically connected to the last turn of the plurality of turns of hollow conductors 1311, and the medium output channel is in communication with a conduit of one end of the last turn of the plurality of turns of hollow conductors 1311. The first turn and the last turn are relative to a current direction. That is, the first turn of the plurality of turns of hollow conductors 1311 refers to a hollow conductor 1311 through which the current flows first, and the last turn of the plurality of turns of hollow conductors 1311 refers to a hollow conductor 1311 through which the current flows last.

It is understandable that the gradient coil 1 may not include the input adapter device 17 or the output adapter device 18. For example, for a certain turn of hollow conductor 1311, the current and the cooling medium output from the turn of hollow conductor 1311 may be introduced through different structures respectively.

The input adapter device 17 is configured to connect to an external power supply and receive the cooling medium. In some embodiments, the input adapter device 17 is connected to the external power supply, an input end of the first turn of the plurality of turns of hollow conductors 1311, and the cooling device 2. The first turn of hollow conductor 1311 refers to a hollow conductor 1311 through which the current flows first in the plurality of turns of hollow conductors 1311.

The first terminal 171 is configured to connect to the external power supply. In some embodiments, two ends of a wire made of a high conductivity material may be disposed on the first terminal 171 and an inner wall of the first interface 173.

The medium input channel 172 is configured to input the cooling medium into the first turn of hollow conductor 1311. In some embodiments, one end of the medium input channel 172 is in communication with a supply pipeline or the input distribution device 152, and the other end is in communication with the conduit 13111 of the first turn of hollow conductor 1311, thereby inputting the cooling medium into the first turn of hollow conductor 1311.

The first interface 173 is configured to connect to the first turn of hollow conductor 1311. In some embodiments, a shape and a size of the first interface 173 are adapted to a shape and a size of the first turn of hollow conductor 1311. When the first turn of hollow conductor 1311 is connected to the first interface 173 and the external power supply is connected to the first terminal 171, the first turn of hollow conductor 1311 conducts electricity with the wire on the inner wall of the first interface 173, thereby achieving electrical connection between the first terminal 171 and the first turn of hollow conductor 1311.

The output adapter device 18 is configured to connect to the external power supply and recover the cooling medium. In some embodiments, the output adapter device 18 is connected to the external power supply, an output end of the last turn of the plurality of turns of hollow conductors 1311, and the cooling device 2. The last turn of hollow conductor 1311 refers to a hollow conductor 1311 through which the current flows last in the plurality of turns of hollow conductors 1311.

The second terminal 181 is configured to connect to the external power supply. In some embodiments, two ends of a wire made of a high conductivity material may be disposed on the second terminal 181 and an inner wall of the second interface 183.

The medium output channel 182 is configured to recover the cooling medium from the last turn of hollow conductor 1311. In some embodiments, one end of the medium output channel 182 is in communication with a recovery pipeline or the outflow collection device 153, and the other end is in communication with the conduit 13111 of the last turn of hollow conductor 1311, thereby recovering the cooling medium from the last turn of hollow conductor 1311.

The second interface 183 is configured to connect to the last turn of hollow conductor 1311. In some embodiments, a shape and a size of the second interface 183 are adapted to a shape and a size of the last turn of hollow conductor 1311. When the last turn of hollow conductor 1311 is connected to the second interface 183 and the external power supply is connected to the second terminal 181, the last turn of hollow conductor 1311 conducts electricity with the wire on the inner wall of the second interface 183, thereby achieving electrical connection between the second terminal 181 and the last turn of hollow conductor 1311.

In some embodiments of the present disclosure, by providing the input adapter device and the output adapter device, input and output of the current and the cooling medium are achieved.

Merely by way of example, as shown in FIG. 5, the conductor structure 13 includes a first coil unit 131-1 and a second coil unit 131-2. The first coil unit 131-1 includes a first hollow conductor 1311a and a second hollow conductor 1311b wound that are in a spatially parallel arrangement. The second coil unit 131-2 includes a third hollow conductor 1311c and the fourth hollow conductor 1311d that are in a spatially parallel arrangement. The embodiment exemplarily illustrates that the first coil unit 131-1 and the second coil unit 131-2 only include a pair of hollow conductors. The gradient coil 1 further includes a first electro-hydraulic separation adapter device 14-1, the second electro-hydraulic separation adapter device 14-2, a first input adapter device 17-1, a second input adapter device 17-2, a first output adapter device 18-1, and a second output adapter device 18-2. The first input adapter device 17-1 is connected to the first hollow conductor 1311a (which may be understood as a first turn of hollow conductor 1311 of the first coil unit 131-1), and the first output adapter device 18-1 is connected to the second hollow conductor 1311b (which may be understood as a last turn of hollow conductor 1311 of the first coil unit 131-1). The second input adapter device 17-2 is connected to the third hollow conductor 1311c (which can be understood as a first turn of hollow conductor 1311 of the second coil unit 131-2), and the second output adapter device 18-2 is connected to the fourth hollow conductor 1311d (which can be understood as a last turn of hollow conductor 1311 of the second coil unit 131-2).

Delivery of the current and the cooling medium for the first coil unit 131-1 and the second coil unit 131-2 are independent and simultaneous, and delivery of the current and the cooling medium for the first coil unit 131-1 is similar to that of the second coil unit 131-2.

Taking the first coil unit 131-1 as an example, a current delivery path is as follows. The current is input from an external power supply to the first transmission adapter device 17-1, then flows sequentially through the first hollow conductor 1311a, the first electro-hydraulic separation adapter device 14-1, the second hollow conductor 1311b, and the first output adapter device 18-1, and is output to the external power supply through the first output adapter device 18-1 to form a current loop in series.

Taking the first coil unit 131-1 as an example, the cooling medium delivery path is as follows. For the first hollow conductor 1311a, the cooling medium is input from the cooling device 2 to the first input adapter device 17-1, then flows through the first hollow conductor 1311a, and is output to the cooling device 2 through the first electro-hydraulic separation adapter device 14-1. For the second hollow conductor 1311b, the cooling medium is input from the cooling device 2 to the first electro-hydraulic separation adapter device 14-1, then flows through the second hollow conductor 1311b, and is output to the cooling device 2 through the first output adapter device 18-1. It is worth noting that the delivery of the cooling medium for the first hollow conductor 1311a and the delivery of the cooling medium for the second hollow conductor 1311b are performed simultaneously.

With such a configuration, the plurality of hollow conductors 1311 are connected in series in the circuit and are connected in parallel in the conduit, thereby reducing the cooling path and improving the cooling efficiency.

In some embodiments, each of the plurality of conductor structures 13 includes a plurality of coil units 131, and the gradient coil 1 further includes the input adapter device 17. The input adapter device includes the first terminal 171, the medium input channel 172, and the first interface 173. The medium input channel 172 receives the cooling medium output from the cooling device 2. The first interface 173 is configured to connect to one end of a first turn of the plurality of turns of hollow conductors 1311 of one of the plurality of coil units 131, the first terminal 171 is electrically connected to the one end of the first turn of the plurality of turns of hollow conductors 1311, and the medium input channel 172 is in communication with the conduit 1311 of the one end of the first turn of the plurality of turns of hollow conductors 1311. A last turn of the plurality of turns of hollow conductors 1311 is electrically connected to a first turn of the plurality of turns of hollow conductors 1311 of another one of the plurality of coil units 131. The conduit 13111 of the last turn of the plurality of turns of hollow conductors 1311 delivers the cooling medium to the cooling device 2.

Merely by way of example, as shown in FIG. 6, the conductor structure 13 includes the first coil unit 131-1 and the second coil unit 131-2. The first coil unit 131-1 includes the first hollow conductor 1311a and the second hollow conductor 1311b that are in a spatially parallel arrangement. The second coil unit 131-2 includes the third hollow conductor 1311c and the fourth hollow conductor 1311d that are in a spatially parallel arrangement. The gradient coil 1 further includes the input adapter device 17, the first electro-hydraulic separation adapter device 14-1, the second electro-hydraulic separation adapter device 14-2, a third electro-hydraulic separation adapter device 14-3, a fourth electro-hydraulic separation adapter device 14-4, and the output adapter device 18.

The first hollow conductor 1311a is connected to the input adapter device 17 and the first electro-hydraulic separation adapter device 14-1, respectively. The second hollow conductor 1311b is connected to the first electro-hydraulic separation adapter device 14-1 and the second electro-hydraulic separation adapter device 14-2, respectively. The third hollow conductor 1311c is connected to the third electro-hydraulic separation adapter device 14-3 and the fourth electro-hydraulic separation adapter device 14-4, respectively. The fourth hollow conductor 1311d is connected to the fourth electro-hydraulic separation adapter device 14-4 and the output adapter device 18, respectively. The second electro-hydraulic separation adapter device 14-2 is disposed in a middle of a winding trajectory of the first coil unit 131-1. The fourth electro-hydraulic separation adapter device 14-4 is disposed in a middle of a winding trajectory of the second coil unit 131-2. The second electro-hydraulic separation adapter device 14-2 and the fourth electro-hydraulic separation adapter device 14-4 are electrically connected through the third connecting conductor 151-2. The third connecting conductor 151-2 may be a hollow or solid wire.

The current delivery path is as follows. The current is input from the external power supply to the input adapter device 17, then flows sequentially through the first hollow conductor 1311a, the first electro-hydraulic separation adapter device 14-1, the second hollow conductor 1311b, the second electro-hydraulic separation adapter device 14-2, the third connecting conductor 151-2, the fourth electro-hydraulic separation adapter device 14-4, the third hollow conductor 1311c, the third electro-hydraulic separation adapter device 14-3, the fourth hollow conductor 1311d, and is output from the output adapter device 18 to the external power supply to form a closed loop.

The cooling medium delivery path is as follows. For the first hollow conductor 1311a, the cooling medium is input from the cooling device 2 to the first hollow conductor 1311a through the input adapter device 17, and is output to the cooling device 2 through the first electro-hydraulic separation adapter device 14-1. For the second hollow conductor 1311b, the cooling medium is input from the cooling device 2 to the second hollow conductor 1311b through the first electro-hydraulic separation adapter device 14-1, and is output to the cooling device 2 through the second electro-hydraulic separation adapter device 14-2. For the third hollow conductor 1311c, the cooling medium is input from the cooling device 2 through the fourth electro-hydraulic separation adapter device 14-4 to the third hollow conductor 1311c, and is output through the third electro-hydraulic separation adapter device 14-3 to the cooling device 2. For the fourth hollow conductor 1311d, the cooling medium is input from the cooling device 2 to the fourth hollow conductor 1311d through the third electro-hydraulic separation adapter device 14-3, and is output to the cooling device 2 through the output adapter device 18. It is worth noting that the delivery of the cooling medium for the first hollow conductor 1311a, the delivery of the cooling medium for the second hollow conductor 1311b, the delivery of the cooling medium for the third hollow conductor 1311c, and the delivery of the cooling medium for the fourth hollow conductor 1311d are performed simultaneously.

With such a configuration, the plurality of hollow conductors are connected in series in the circuit and are connected in parallel in the conduit, thereby reducing the cooling path and improving the cooling efficiency.

Merely by way of example, as shown in FIG. 7, the conductor structure 13 includes the first coil unit 131-1 and the second coil unit 131-2. The first coil unit 131-1 includes the first hollow conductor 1311a and the second hollow conductor 1311b that are in a spatially parallel arrangement. The second coil unit 131-2 includes the third hollow conductor 1311c and the second hollow conductor 1311d that are in a spatially parallel arrangement.

Structure of the second coil unit 131-2 is the same as that of the first coil unit 131-1. The first coil unit 131-1 is taken as an example for description below.

The gradient coil 1 further includes the input adapter device 17, the adapter device 16, the electro-hydraulic separation adapter device 14, the output adapter device 18, and the second connecting conductor 151-1. The first hollow conductor 1311a is connected to the input adapter device 17 and the electro-hydraulic separation adapter device 14, respectively, and the second hollow conductor 1311b is connected to the adapter device 16 and the output adapter device 18, respectively. The adapter device 16 and the electro-hydraulic separation adapter device 14 are electrically connected through the second connecting conductor 151-2. The input adapter device 17 and the adapter device 16 are disposed in a middle of the winding trajectory of the first coil unit 131-1.

A current delivery path is as follows. The current is input from an external power supply to the input adapter device 17, then flows sequentially through the first hollow conductor 1311a, the electro-hydraulic separation adapter device 14, the second connecting conductor 151-2, the adapter device 16, the second hollow conductor 1311b, and is output from the output adapter device 18 to the external power supply to form a closed loop.

A cooling medium delivery path is as follows. For the first hollow conductor 1311a, the cooling medium is input from the cooling device 2 through the input adapter device 17-1 to the first hollow conductor 1311a, and is output to the cooling device 2 through the electro-hydraulic separation adapter device 14. For the second hollow conductor 1311b, the cooling medium is input from the cooling device 2 through the adapter device 16 to the second hollow conductor 1311b, and is output through the output adapter device 18 to the cooling device 2. It is worth noting that the delivery of the cooling medium for the first hollow conductor 1311a and the delivery of the cooling medium for the second hollow conductor 1311b air performed simultaneously.

With such a configuration, the plurality of hollow conductors are connected in series in the circuit and are connected in parallel in the conduit, thereby reducing the cooling path and improving the cooling efficiency.

In some embodiments, as shown in FIG. 5 to FIG. 7, each of the plurality of hollow conductors 1311 includes a first end M and a second end N. Each of the plurality of hollow conductors 1311 is wound in a spiral shape either from the inside out or from the outside in. The first end Mis an end located at a center of the spiral shape, and the second end N is an end located at an outer side of the spiral shape. The electro-hydraulic separation adapter device 14 is located at the first end M, or the electro-hydraulic separation adapter device 14 is located at the second end N.

From the inside out and from the outside in refer to winding directions of the plurality of hollow conductors 1311. It should be noted that, regardless of whether the winding is from the inside out or from the outside in, the final product obtained by winding may be the same, i.e., a coil with the spiral shape coiled clockwise or counterclockwise is obtained.

In some embodiments of the present disclosure, by disposing the plurality of hollow conductors at the end located at the center or at the end located at the outer side of the spiral shape, the electro-hydraulic separation adapter devices can be concentrated on the same side of the coil unit when the plurality of hollow conductors are provided, thereby optimizing the structural layout and achieving a better imaging effect.

In some embodiments, each of the plurality of conductor structures 13 includes a plurality of coil units 131, and the last one of the plurality of hollow conductors 1311 of one of the plurality of coil units 131 is connected to the first one of the plurality of hollow conductors 1311 of another one of the plurality of coil units 131.

For example, as shown in FIG. 6, when the conductor structure 13 includes two coil units 131 (e.g., the first coil unit 131-1 and the second coil unit 131-2), the last turn of hollow conductor 1311 (the second hollow conductor 1311b) of the first coil unit 131-1 is connected to the first turn of hollow conductor 1311 (the third hollow conductor 1311c) of the second coil unit 131-2.

With such a configuration, the circuits of the plurality of coil units within a single conductor structure can be connected in series, and the count of adapter devices are reduced, thereby reducing the count of wires and devices to reduce the space occupied by these devices, which leaves more space for the coil and optimizes the layout.

In some embodiments, when the last turn of the plurality of turns of hollow conductors 1311 of one of the plurality of coil units 131 is connected to the first turn of the plurality of turns of hollow conductors 1311 of another one of the plurality of coil units 131, the adapter device 16 may be disposed at the second end N. Then, the current of the last turn of the plurality of turns of hollow conductors 1311 flows from the outer side of the spiral shape toward the center, and connecting the two centers can achieve electrical connection of the two coil units, thereby shortening the length of the wire connecting the two coil units and preventing the wire from occupying the lead-out space of the wire.

In some embodiments, as shown in FIG. 5 to FIG. 7, the plurality of coil units 131 include the first coil unit 131-1 and the second coil unit 131-2, and there is a distance between the first coil unit 131-1 and the second coil unit 131-2 along the axial direction S of the gradient coil 1. The axial direction S refers to a direction along a central axis of a cylinder. The distance in the axial direction may be understood as the first coil unit 131-1 and the second coil unit 131-2 being separated from each other by a preset distance in the axial direction S of the gradient coil 1. The preset distance is determined based on experience. The preset distance may be 0, in which case the first coil unit 131-1 and the second coil unit 131-2 are adjacent to each other without overlapping along the axial direction S of the gradient coil 1. With such an arrangement, the imaging effect of the two coil units can be ensured.

Understandably, the plurality of coil units 131 may further include more than two coil units 131. For example, the plurality of coil units 131 includes the first coil unit 131-1, the second coil unit 131-2, a third coil unit, and a fourth coil unit.

FIG. 12 is a schematic diagram illustrating a partial three-dimensional structure of an exemplary coil according to some embodiments of the present disclosure.

In some embodiments, as shown in FIG. 12, the first coil unit 131-1 includes a first transmission conductor 131-11 connected to the plurality of hollow conductors 1311. The second coil unit 131-2 includes a second transmission conductor 131-21 connected to the plurality of hollow conductors 1311. The first transmission conductor 131-11 and the second transmission conductor 131-21 are led out from different ends of the gradient coil 1 along the axial direction S of the gradient coil 1.

A transmission conductor is configured to implement a circuit connection and a conduit connection of the plurality of hollow conductors 1311.

By way of example, as shown in FIG. 12, the first transmission conductor 131-11 includes two transmission sub-conductors, one of the two transmission sub-conductors is connected to the first hollow conductor 1311a, and the other of the two transmission sub-conductors is connected to the second hollow conductor 1311b. Similar to the first transmission conductor 131-11, the second transmission conductor 131-21 also includes two transmission sub-conductors, one of the two transmission sub-conductors is connected to the third hollow conductor 1311c, and the other of the two transmission sub-conductors is connected to the fourth hollow conductor 1311d. A lead-out direction of the first transmission conductor 131-11 and a lead-out direction of the second transmission conductor 131-21 are opposite to each other along the axial direction S.

In some embodiments of the present disclosure, if the two transmission conductors are both led out from the same side in the axial direction of the gradient coil, the reserved space for the hollow conductors needs to be compressed to reserve more space for the two transmission conductors, which affects the performance of the coil. By setting the lead-out directions of the two transmission conductors to be led out from different ends of the gradient coil along the axial direction of the gradient coil, the space occupied by the two transmission conductors can be reduced, thereby improving the performance of the gradient coil.

In some embodiments, the plurality of conductor structures include two conductor structures spaced apart from each other, wherein the two conductor structures are spaced apart along a circumferential direction of the gradient coil 1, and a spacing between the two conductor structures forms a lead-out slot.

In some embodiments, as shown in FIG. 1, the X-coil 11 includes a first conductor structure 13-1 and a second conductor structure 13-2 spaced apart from each other, wherein the first conductor structure 13-1 and the second conductor structure 13-2 are spaced apart along a circumferential direction L of the gradient coil 1, and a spacing between the first conductor structure 13-1 and the second conductor structure 13-2 forms a first lead-out slot 111. The Y-coil 12 includes a third conductor structure 13-3 and a fourth conductor structure 13-4 spaced apart from each other, wherein the third conductor structure 13-3 and the fourth conductor structure 13-4 are spaced apart along the circumferential direction L of the gradient coil 1, and a spacing between the third conductor structure 13-3 and the fourth conductor structure 13-4 forms a second lead-out slot 121. The first lead-out slot 111 and the second lead-out slot 121 are arranged in a staggered manner along the circumferential direction L of the gradient coil 1.

The circumferential direction L refers to a circumferential direction of the cylindrical gradient coil 1. Spaced apart along the circumferential direction may be understood as: end portions of the first conductor structure 13-1 and the second conductor structure 13-2 are separated from each other along the circumferential direction L of the gradient coil 1.

The first lead-out slot 111 is used for leading out pipelines and lines of the first conductor structure 13-1 and the second conductor structure 13-2. In some embodiments, two first lead-out slots 111 may be formed between the first conductor structure 13-1 and the second conductor structure 13-2.

The second lead-out slot 121 is used for leading out pipelines and lines of the third conductor structure 13-3 and the fourth conductor structure 13-4. In some embodiments, similar to the first lead-out slot 111, two second lead-out slots 121 may be formed between the third conductor structure 13-3 and the fourth conductor structure 13-4.

Being arranged in the staggered manner may be understood as projections of the two first lead-out slots 111 and the two second lead-out slots 121 on the circumferential direction L of the gradient coil 1 not overlapping. Merely by way of example, the first lead-out slot 111 may be arranged at 90° and 270°, and the second lead-out slot 121 may be arranged at 0° and 180°, thereby achieving being arranged in the staggered manner.

By way of example, a staggered angle between the lead-out slot 111 of the X-coil 11 and the lead-out slot 121 of the Y-coil 12 is 90 degrees. As shown in FIG. 1, starting from the inner side, the innermost is the X-coil 11, which includes two spaced-apart semi-circular saddle-shaped coils distributed in a 0° direction and a 180° direction. A middle layer is the Y-coil 12, which also includes two spaced-apart semi-cylindrical coils distributed in a 90° direction and a 270° direction. An outer layer is the Z-coil 20, which is a complete cylindrical structure. With such a configuration, gradient magnetic fields in an X direction, a Y direction, and a Z direction are formed to ensure a scanning effect.

In some embodiments, the gradient coil 1 includes a transmission conductor assembly connected to the plurality of hollow conductors 1311, the first transmission conductor assembly is disposed in the lead-out slot.

In some embodiments, as shown in FIG. 1 and FIG. 12, the X-coil 11 includes a first transmission conductor assembly 112 connected to the plurality of hollow conductors 1311 of the X-coil 11, and the first transmission conductor assembly 112 is disposed in the second lead-out slot 121.

The first transmission conductor assembly 112 refers to pipelines and lines (e.g., conduits and cables) that need to be led out from the first conductor structure 13-1 and the second conductor structure 13-2. In some embodiments, one conductor structure 13 is provided with two first transmission conductor assemblies 112 that are opposite to each other along the axial direction of the gradient coil 1, and one of the two first transmission conductor assemblies 112 is led out from one of the two second lead-out slots 121. In some embodiments, the first transmission conductor assembly 112 is arranged side by side and led out from the second lead-out slot 121, and an arrangement width along the circumferential direction L is less than a slot width of the second lead-out slot 121.

In some embodiments, the first transmission conductor assembly 112 includes a total water inlet 210, a total water outlet 220, a current inlet 230, and a current outlet 240. The total water inlet 210 is used for introducing a cooling medium into the gradient coil 1. The total water outlet 220 is used for leading out the cooling medium of the gradient coil 1. The current inlet 230 is used for introducing a current into the gradient coil 1. The current outlet 240 is used for leading out the current of the gradient coil 1.

In some embodiments, the Y-coil 12 includes a second transmission conductor assembly connected to the plurality of hollow conductors 1311 of the Y-coil 12, and the second transmission conductor assembly is disposed in the first lead-out slot 111.

Similar to the first transmission conductor assembly, the second transmission conductor assembly refers to pipelines and lines that need to be led out from the third conductor structure 13-3 and the fourth conductor structure 13-4. In some embodiments, one conductor structure 13 is provided with two second transmission conductor assemblies that are opposite to each other along the axial direction of the gradient coil 1, and one of the two second transmission conductor assemblies is led out from one of the two first lead-out slots 121. In some embodiments, the second transmission conductor assembly is arranged side by side and led out from the first lead-out slot 111, and an arrangement width along the circumferential direction L is less than a slot width of the first lead-out slot 111.

In some embodiments of the present disclosure, if pipelines and lines of the X-coil and the Y-coil are led out from the same end in the circumferential direction of the cylindrical structure, the size of the conductor structure needs to be compressed to reserve a larger space for the lead-out slots. By arranging the plurality of lead-out slots in the staggered manner, more space can be saved for setting the conductor structure, thereby ensuring the performance of the gradient coil. At the same time, by setting the lead-out slots, the pipelines and lines of the X-coil and the Y-coil can be led out from both ends and set in the lead-out slots, and the travel of the pipelines and lines of the X-coil and the Y-coil extending from the cylindrical structure can be reduced, thereby reducing the water path and improving cooling efficiency. Understandably, under the premise that the performance of the gradient coil remains unchanged, the size of the circumferential interval of the gradient coil is fixed. The more pipelines that can be accommodated, the more the water path is shortened, and the higher the cooling efficiency.

FIG. 13 is a schematic diagram illustrating an exemplary water distribution device according to some embodiments of the present disclosure.

In some embodiments, a water distribution device includes a primary water distribution device and a secondary water distribution device. The input distribution device 152 and the outflow collection device 153 may serve as the primary water distribution device, and the total water inlet 210 and the total water outlet 220 may serve as the secondary water distribution device, referring to FIG. 12. Through the primary water distribution device, the cooling medium of each layer of coils (such as any one of the X-coil 11, the Y-coil 12, and the Z-coil 20) may be converged to the total water inlet 210 and the total water outlet 220. Through the secondary water distribution device, the cooling medium of all the multi-layer coils (i.e., the main coil 10 and the shielding coil 30) may be converged and then led to the water inlet connection end 250-1 and the water outlet connection end 250-2 (referring to FIG. 13), and the water inlet connection end 250-1 and the water outlet connection end 250-2 are connected to the cooling device 2.

In some embodiments, as shown in FIG. 12, each the plurality of conductor structure 13 includes a support component 132, one or more coil units 131 are supported and fixed on the support component 132, and the support component 132 is of a cylindrical or semi-cylindrical structure.

The support component 132 is used for supporting the one or more coil units 131 to avoid deformation of the one or more coil units.

The cylindrical structure refers to a support component with a circumference of 360°. In some embodiments, when the X-coil 11, the Y-coil 12, and the Z-coil 20 need to be uniformly and symmetrically distributed over the entire circumference to generate a uniform gradient magnetic field, the support component 132 of the cylindrical structure may be adopted.

The semi-cylindrical structure refers to a support component 132 with a circumference of 180°. In some embodiments, when the X-coil 11, the Y-coil 12, and the Z-coil 20 are only arranged on a circumferential portion corresponding to an imaging area, the support component 132 of the semi-cylindrical structure may be adopted. Understandably, two support components 132 of the semi-cylindrical structure may enclose a complete cylindrical structure, or a cylindrical structure with a gap along the circumferential direction L, so that the gradient magnetic field is formed over the entire circumferential direction L, ensuring the scanning effect.

In some embodiments, a portion or all of the one or more coil units 131 is embedded in the support component 132. The support component 132 serves to support and fix the conductive coil unit on one hand, and serves as an insulator on the other hand.

In some embodiments of the present disclosure, by setting the support component, deformation of the each of the plurality of conductor structures can be avoided, thereby ensuring the function of the gradient coil.

Embodiments of the present disclosure provide a gradient coil 1. The gradient coil 1 includes the first hollow conductor 1311a and the second hollow conductor 1311b, the first hollow conductor 1311a and the second hollow conductor 1311b form concentric loops, the a first hollow conductor 1311a includes a first conduit for a cooling medium to flow through, the second hollow conductor 1311b includes a second conduit for the cooling medium to flow through, the first conduit and the second conduit form a parallel cooling circuit.

More descriptions regarding the first hollow conductor 1311a and the second hollow conductor 1311b may be found in the foregoing.

The concentric loop refers to a structure where the first hollow conductor 1311a and the second hollow conductor 1311b are arranged in an annular nested manner with a common central axis as the center. The parallel cooling circuit refers to a structural form where the first conduit of the first hollow conductor 1311a and the second conduit of the second hollow conductor 1311b are connected to the cooling device 2 simultaneously as two mutually independent flow paths for the cooling medium.

In some embodiments, the first hollow conductor 1311a and the second hollow conductor 1311b are connected in series in a circuit. In some embodiments, gradient coil 1 includes one or more coil units 131, each of the one or more coil units 131 is cooled via the first conduit and the second conduit. In some embodiments, one end of each of the first hollow conductor 1311a and the second hollow conductor 1311b receives the cooling medium from the cooling device 2, and the other end of each of the first hollow conductor 1311a and the second hollow conductor 1311b delivers the cooling medium to the cooling device 2. More descriptions may be found in the foregoing.

In some embodiments, a length of each of the first conduit and the second conduit is less than a total length of the concentric loops formed by the first hollow conductor and the second hollow conductor. With such a configuration, the cooling path is greatly shortened, and the cooling efficiency is significantly improved.

Embodiments of the present disclosure provide a magnetic resonance imaging device. The magnetic resonance imaging device includes the gradient coil 1 according to any one of the foregoing embodiments.

The basic concepts have been described above. Obviously, to those skilled in the art, the foregoing detailed disclosure is merely by way of example and does not constitute a limitation to the present disclosure. Although not explicitly stated herein, those skilled in the art may make various modifications, improvements, and amendments to the present disclosure. Such modifications, improvements, and amendments are suggested in the present disclosure. Therefore, such modifications, improvements, and amendments still fall within the spirit and scope of the exemplary embodiments of the present disclosure.

Finally, it should be understood that the embodiments in the present disclosure are merely used to illustrate the principles of the embodiments of the present disclosure. Other variations may also fall within the scope of the present disclosure. Therefore, by way of example and not limitation, alternative configurations of the embodiments of the present disclosure may be considered consistent with the teachings of the present disclosure. Accordingly, the embodiments of the present disclosure are not limited to the embodiments explicitly introduced and described in the present disclosure.

What is claimed is:

1. A gradient coil, comprising a plurality of conductor structures,
each of the plurality of conductor structures includes one or more coil units wound in a concentric manner,
each of the one or more coil units includes a plurality of hollow conductors, and a conduit for a cooling medium to pass through is disposed within each of the plurality of hollow conductors,
the plurality of hollow conductors are connected in series in a circuit, and at least two conduits of the plurality of hollow conductors are connected in parallel.

2. The gradient coil of claim 1, further comprising one or more electro-hydraulic separation adapter devices, wherein
each of the one or more electro-hydraulic separation adapter devices effects a series circuit connection between a pair of the plurality of hollow conductors.

3. The gradient coil of claim 2, wherein
the electro-hydraulic separation adapter device includes a first connecting conductor,
the coil unit includes a first hollow conductor and a second hollow conductor,
one end of the first hollow conductor and one end of the second hollow conductor are electrically connected by the first connecting conductor.

4. The gradient coil of claim 2, wherein the electro-hydraulic separation adapter device leads out the cooling medium from a conduit of one of the pair of the plurality of hollow conductors.

5. The gradient coil of claim 4, wherein the electro-hydraulic separation adapter device introduces the cooling medium into the other of the pair of the plurality of hollow conductors.

6. The gradient coil of claim 4, wherein
the electro-hydraulic separation adapter device includes a first medium interface,
the coil unit includes a first hollow conductor and a second hollow conductor,
one end of the first hollow conductor is in communication with the first medium interface,
the other end of the first hollow conductor receives the cooling medium, and
one end of the second hollow conductor receives the cooling medium.

7. The gradient coil of claim 6, wherein
the electro-hydraulic separation adapter device further includes a second medium interface, and
the one end of the second hollow conductor is in communication with the second medium interface.

8. The gradient coil of claim 6, further comprising a second connecting conductor and an adapter device, wherein
the one end of the second hollow conductor is connected to the adapter device, the adapter device receives the cooling medium from a cooling device, one end of the second connecting conductor is electrically connected to the one end of the second hollow conductor by the adapter device, and the other end of the second connecting conductor is electrically connected to the first connecting conductor.

9. The gradient coil of claim 1, wherein each of the plurality of hollow conductors is connected to a cooling device, one end of each of the plurality of hollow conductors receives the cooling medium output from a cooling device, and the other end of the each of the plurality of hollow conductors delivers the cooling medium to the cooling device.

10. The gradient coil of claim 3, wherein each of the plurality of hollow conductors includes a first end and a second end, each of the plurality of hollow conductors is wound in a spiral shape either from the inside out or from the outside in, the first end is an end located at a center of the spiral shape, and the second end is an end located at an outer side of the spiral shape, and
the electro-hydraulic separation adapter device is located at the first end, or the electro-hydraulic separation adapter device is located at the second end.

11. The gradient coil of claim 1, wherein each of the plurality of conductor structures includes a plurality of coil units, and
a last one of the plurality of hollow conductors of one of the plurality of coil units is connected to a first one of the plurality of hollow conductors of another one of the plurality of coil units.

12. The gradient coil of claim 1, wherein the plurality of coil units include a first coil unit and a second coil unit, the first coil unit includes a first transmission conductor connected to the plurality of hollow conductors, the second coil unit includes a second transmission conductor connected to the plurality of hollow conductors, and the first transmission conductor and the second transmission conductor are led out from different ends of the gradient coil along an axial direction of the gradient coil.

13. The gradient coil of claim 1, wherein the plurality of conductor structures include two conductor structures spaced apart from each other, wherein the two conductor structures are spaced apart along a circumferential direction of the gradient coil, and a spacing between the two conductor structures forms a lead-out slot.

14. The gradient coil of claim 13, further comprising a transmission conductor assembly connected to the plurality of hollow conductors, the first transmission conductor assembly is disposed in the lead-out slot.

15. A gradient coil, comprising a first hollow conductor and a second hollow conductor,
wherein the first hollow conductor and the second hollow conductor form concentric loops, the a first hollow conductor includes a first conduit for a cooling medium to flow through, the second hollow conductor includes a second conduit for the cooling medium to flow through, the first conduit and the second conduit form a parallel cooling circuit.

16. The gradient coil of claim 15, wherein the first hollow conductor and the second hollow conductor are connected in series in a circuit.

17. The gradient coil of claim 15, further comprising one or more coil units, wherein each of the one or more coil units is cooled via the first conduit and the second conduit.

18. The gradient coil of claim 15, wherein a length of each of the first conduit and the second conduit is less than a total length of the concentric loops formed by the first hollow conductor and the second hollow conductor.

19. The gradient coil of claim 15, wherein one end of each of the first hollow conductor and the second hollow conductor receives a cooling medium from a cooling device, and the other end of each of the first hollow conductor and the second hollow conductor delivers the cooling medium to the cooling device.

20. A magnetic resonance imaging (MRI) apparatus, comprising a gradient coil, wherein the gradient coil includes a plurality of conductor structures,
each of the plurality of conductor structures includes one or more coil units wound in a concentric manner,
each of the one or more coil units includes a plurality of hollow conductors, and a conduit for a cooling medium to pass through is disposed within each of the plurality of hollow conductors,
the plurality of hollow conductors are connected in series in a circuit, and at least two conduits of the plurality of hollow conductors are connected in parallel.
